(19) United States
(12) Patent Application Publication
(10) Pub. No.: US 2017/0107622 A1
(43) Pub. Date: Apr. 20, 2017

(54) METHOD FOR PREVENTING INTERFERENCE COLORS ON THINLY COATED METAL SURFACES

(71) Applicant: BSH Hausgeräte GmbH, Munich (DE)

(72) Inventors: Frank Jördens, Traunstein (DE); Jürgen Salomon, Trostberg (DE); Philipp Schaller, Traunreut (DE); Gerhard Schmidmayer, Bad Endorf (DE)

(21) Appl. No.: 15/315,789

(22) PCT Filed: Jun. 3, 2015
(86) PCT No.: PCT/EP2015/062332

§ 371 Date: Dec. 2, 2016

(30) Foreign Application Priority Data
Jun. 5, 2014 (DE) 10 2014 210 671.0

(51) Int. Cl. C23C 16/50; C23C 14/22

(52) U.S. Cl. CPC C23C 16/50; C23C 14/22

(57) ABSTRACT

In a method for finishing a metal surface of a component, the metal surface of a main part of the component is coated with an intermediate layer. The intermediate layer can have a layer thickness of less than 100 nm. Applied onto the intermediate layer is a transparent functional layer which has a layer thickness ranging from 100 to 1000 nm.

### TECHNICAL FIELD

The present invention relates to methods for coating or surface finishing of components having metal surfaces, in particular coatings to prevent or reduce interference colors in thin and transparent functional coatings on metal components for e.g. household devices.

The present invention further relates to components having metal surfaces which have the above-mentioned coatings.

### PRIOR ART

Many metal components in household devices are provided with a thin transparent coating, referred to in the following as a “functional coating”, for improving their performance characteristics (e.g. smear resistance, scratch resistance, corrosion protection, frictional characteristics, diffusion-inhibiting effect, biocompatibility, wettability, electrical characteristics). For example, oven shelves made of stainless steel have increased resistance to high temperatures and chemicals (e.g. pyrolysis stability) thanks to a thin SiO₂ layer (which is produced e.g. in the PECVD method). However, if the layer strength of the applied coating is of a similar order of magnitude to the wavelength of visible light (i.e. approx. 100-1000 nm), interference effects result in the formation of interference colors (“rainbow colors”) perceived as objectionable. This means the metal component no longer appears to have a homogeneous metallic luster, but exhibits—depending on the direction of viewing—yellow, red, blue or green discolorations.

The appearance of these colors can be countered by increasing the layer thickness of the transparent coating to over 2000 nm, which however is undesirable for reasons of cost (because e.g. of increased use of materials or significantly extended coating times in the CVD/PVD method) or is not practicable because of the resultant mechanical characteristics (e.g. brittleness of the layer or increase in the propensity to crack, which can lead to loss of function).

The modification of the roughness of metal surfaces to minimize interference phenomena is a known alternative way of increasing the thickness of the functional coating.

Thus DE 100 64 134 A1 discloses a method in which the interference is suppressed by a mechanical and/or chemical and/or physical roughening of the metal surface. In this connection ‘physical roughening’ means the (physical) introduction of second phases (such as light-scattering particles or pores), as well as grinding or blasting, in particular sand or shot blasting. One example of chemical roughening is etching, e.g. using acids such as phosphoric, sulfuric or hydrochloric acid to produce a microstructure in the surface to be treated.

Furthermore, the physical roughening by the addition of light-scattering particles such as TiO₂, Al₂O₃, ZrO₂ or SiO₂ can take place as part of a sol-gel process.

DE 10 2008 011 298 A1 further discloses a method for treating the surface of aluminum components, which provides for the production of an anodized surface with a comb-like or pore structure, the introduction and oxidation of pigmented substances into the pores or depressions, and the application of a pigmented cover layer. In so doing, optical interference is suppressed by the pigmentations in the pores or cover layer and the coloring is suppressed by the oxidized substances.

EP 1 652 963 A1 discloses a combination of the above approaches for preventing unwanted reflections. Specifically, EP 1 652 963 A1 relates to metal main parts, which are provided at least on one portion of the surface with a surface structure which has an average roughness value R_{A} greater than 0.4 μm. A double layer consisting of a high-density fine-crystalline titanium layer with a thickness of 1 μm and a titanium dioxide layer above this, the thickness of which is set at at least 2 μm in order to prevent the appearance of colors caused by interference, is applied to the aforementioned surface structure using plasma-assisted PVD methods.

A disadvantage of the aforementioned methods is generally that because of the roughening process no high-luster reflective metal surfaces can be provided and thus the options for configuring the metal components are limited. As chemical (CVD) or physical (PVD) vapor separation techniques are predominantly used for the application of functional layers, the aforementioned processes furthermore require different technical procedures for the interference-reducing measures (e.g. chemical roughening using sol-gel processes) and the functional coating, which entails a higher outlay in terms of time and cost.

### OBJECT OF THE INVENTION

It is therefore the object of the present invention to provide a low-cost and simple method for surface finishing of metal components, with the aid of which light interference can be reduced or prevented in thin, transparent functional coatings, without having to increase the layer thickness of the functional coating and without the necessity of using different coating methods.

A further object of the present invention is moreover to provide components with metal surfaces which have been finished using the aforementioned method.

### BRIEF DESCRIPTION OF THE INVENTION

It has been found that the reflective characteristics of metal surfaces can be advantageously changed by applying an additional intermediate layer between the functional layer and the metal surface, so that the color effect caused by interference can be significantly abated or suppressed, without increasing the thickness of the functional layer and thus increasing the susceptibility thereof to brittleness and the formation of cracks.

Hence the present invention provides a method for finishing metal surfaces of components as a solution to the aforementioned problems, which is characterized in that it comprises coating the metal surface of a main part contained in the component with an intermediate layer, and applying a transparent functional layer to the intermediate layer, wherein the transparent functional layer has a layer thickness ranging from 100 to 1000 nm.

Furthermore, components manufactured in accordance with the described method are provided by the present invention, which are in particular characterized by a pleasing homogeneous (metal) appearance without the formation of interference colors.

Advantageous embodiments of the invention can be taken from the dependent claims and the following explanations.

### BRIEF DESCRIPTION OF THE FIGURE

FIG. 1 schematically represents the layer structure which is provided by the method according to the present invention.

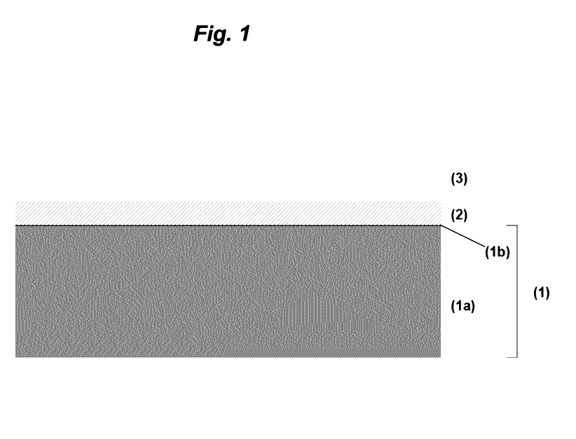

### BEST WAY TO EMBODY THE INVENTION

The invention and its advantages are described below in greater detail on the basis of preferred exemplary embodiments.

Providing it has a metal surface (1b) the main part (1) of the component to be treated is not especially restricted. Hence the base material (1a) can be formed e.g. from solid metal, metal alloys, ceramic or polymers. In one embodiment of the invention the base material (1a) and the metal surface (1b) of the main part (1) consist of the same material, e.g. a metal or a metal alloy.

The metal surface (1b) therefore represents the surface of a metal or of a metal alloy. Preferably the metal surfaces (1b) to be treated are those of stainless steels, in particular surfaces of the steel grades 1.4301 and 1.4016 (chromium nickel steel or chromium steel), particularly preferably the steel grade 1.4016.

According to the invention the interference-color-suppressing intermediate layer (2) is applied to the metal surface (1b) of the main part (1).

The intermediate layer (2) preferably has a thickness of less than 100 nm, particularly preferably a thickness ranging from 2 nm to 90 nm.

The intermediate layer (2) preferably represents a solid layer deposited continuously across the metal surface (1b), which means it differs substantially from individual particles introduced for the purpose of roughening or island-like accumulations or aggregations of individual particles.

For the purpose of the present invention any material can be selected as a material for the intermediate layer (2) which for a given layer thickness has a refractive index (n) and absorption coefficient (k) suitable for minimizing interference. Preferably Ag, Al, Ti and/or their compounds are used as materials for the intermediate layer (2), particularly preferably Ag, Al and TiO₂.

It should be stressed that the intermediate layer (2) can also fulfill other functions (such as for example a smoothing and/or bonding effect) thanks to the appropriate choice of material and layer density, in addition to preventing interference colors.

It is further advantageous that the metallic look can be selectively varied thanks to the appropriate choice of material and layer density. Thus in contrast to the methods known in the prior art, which provide for a roughening of the metal surface (1b), metal surfaces with a very high degree of luster can also be achieved.

The intermediate layer (2) further has the advantage compared to the known methods that the component need not be manufactured completely from the material preventing the interference colors, and that base material for the production of the component can be saved, meaning the manufacturing costs can be minimized.

The application of the intermediate layer (2) to the metal surface can be performed using several known methods. Thus for example coating by means of chemical (CVD) or physical (PVD) gas phase deposition (e.g. sputtering), galvanic methods or sol-gel methods is advantageous for the provision of thin layer thicknesses of less than 100 nm. Likewise other methods, e.g. hot-dip finishing or plating, are conceivable, wherein layer thicknesses of the interference-reducing material of 100 nm or greater are also possible.

The transparent functional coating (3) applied to the intermediate layer (2) has a thickness in the nanometer range. Preferably the thickness of the functional coating (3) is 100 nm or more and less than 1000 nm, in order to guard against the risk of the formation of cracks and brittleness of materials and to prevent extended coating times e.g. in the CVD/PVD method. Particularly preferably a layer thickness ranges from 300 to 800 nm.

In general the functional description (3) can be any known coating for the purposes of improving e.g. flexibility, smear resistance, scratch resistance, corrosion protection, frictional characteristics, diffusion-inhibiting effect, biocompatibility, wettability and/or electrical characteristics. The functional coating (3) can likewise be constructed of multiple layers.

Preferred materials for use for the functional coating (3) can be compounds of Si, Ti, Al, Zr and/or B, such as e.g. TiN, TiBN, TiBC, SiO₂, or Si₃N₄. In a preferred embodiment SiO₂ is used for the functional coating (3).

Like the intermediate layer (2), the functional coating (3) can likewise be applied to the intermediate layer (2) in various known ways, such as e.g. by immersion, centrifugal action, spraying, flooding or rubbing in. Since the respective coating methods can be selected from a large range, it is possible to simplify and accelerate the surface finishing procedure considerably by appropriate coordination, since the application of the interference-reducing intermediate layer (2) and the functional coating (3) can take place serially in the same coating system. Thus compared to the known methods for preventing interference colors on thinly coated metal surfaces (e.g. by physical or chemical roughening) there are other advantages in respect of the duration and cost of the process.

According to a preferred embodiment, the application of the functional coating (3) on the interference-reducing intermediate layer (2) is performed using plasma coating methods (PECVD) which enable the selective provision of thin layers with little use of material and short coating times, and furthermore can be excellently combined with further vacuum methods, such as e.g. evaporation, sputtering, plasma pretreatment and plasma precision cleaning.

Consequently the inventive method provides, not least because of the easily creatable layer properties, an effective and above all relatively inexpensive and efficient solution to the problems described in the introduction.

Another aspect of the present invention relates to a component which has been manufactured using the method described above.

In a preferred embodiment the component represents a household device component, particularly preferably a household device component, e.g. a cooking device component, subjected to heat under conditions of use. In a further preferred embodiment the component is an oven shelf.

The components referred to are characterized in that they have a layer structure manufactured according to the methods described above. In particular they contain a main part (1) consisting of a base material and the metal surface (1b), an intermediate layer (2) applied to the metal surface, and a transparent functional layer (3) applied to the intermediate layer (2), wherein the transparent functional layer (3) has a layer thickness ranging from 100 to 1000 nm.

In preferred embodiments the intermediate layer (2) has a layer thickness of less than 100 nm.

In a further preferred embodiment the transparent functional layer (3) is formed from compounds of Si, Ti, Al, Zr and/or B, particularly preferably SiO₂.

Preferably the intermediate layer (2) is selected from a material formed of Ag, Al, Ti and compounds thereof, particularly preferably of Ag, Al, or TiO₂.

The main part (1) having the metal surface (1b) is preferably formed of stainless steel, particularly preferably a stainless steel with the material number 1.4016.

The characteristics and compositions of the individual layers and the advantages thereof can be taken from the above description of the inventive method.

The cited components are advantageously characterized by a completely uniform metallic look and the absence of optical interference effects, without the function and the physical characteristics of the transparent functional coating being impaired.

### LIST OF REFERENCE CHARACTERS

(1) Main part
(1a) Base material
(1b) Metal surface
(2) Intermediate layer
(3) Transparent functional layer

1-13. (canceled)

14. A method for finishing a metal surface of a component, comprising:
coating the metal surface of a main part of the component with an intermediate layer, and
applying a transparent functional layer at a layer thickness ranging from 100 to 1000 nm to the intermediate layer.

15. The method of claim 14, wherein the intermediate layer has a layer thickness of less than 100 nm.

16. The method of claim 14, wherein the transparent functional layer is formed of compounds of Si, Ti, Al, Zr and/or B.

17. The method of claim 14, wherein the transparent functional layer is formed of SiO₂.

18. The method of claim 14, wherein the intermediate layer is formed from a material selected from the group consisting of Ag, Al, Ti, and compounds thereof.

19. The method of claim 14, wherein the intermediate layer is formed from a material selected from the group consisting of Ag, Al, and TiO₂.

20. The method of claim 14, wherein the metal surface is coated with the intermediate layer by a plasma coating method.

21. The method of claim 14, wherein the transparent functional layer is applied to the intermediate layer by a plasma coating method.

22. The method of claim 14, wherein the metal surface is coated with the intermediate layer and the transparent functional layer is applied to the intermediate layer by a same coating method.

23. The method of claim 14, wherein the main part including the metal surface is formed of stainless steel.

24. The method of claim 23, wherein the stainless steel has a material number 1.4016.

25. A component, comprising:
a main part having a metal surface;
an intermediate layer coated upon the metal surface, and
a transparent functional layer applied to the intermediate layer, said transparent functional layer having a layer thickness ranging from 100 to 1000 nm.

26. The component of claim 25, constructed in the form of a household device component, a cooking device component, or an oven shelf.

27. The component of claim 25, wherein the intermediate layer has a layer thickness of less than 100 nm.

28. The component of claim 25, wherein the transparent functional layer is formed of compounds of Si, Ti, Al, Zr and/or B.

29. The component of claim 25, wherein the transparent functional layer is formed of SiO₂.

30. The component of claim 25, wherein the intermediate layer is formed from a material selected from the group consisting of Ag, Al, Ti, and compounds thereof.

31. The component of claim 25, wherein the intermediate layer is formed from a material selected from the group consisting of Ag, Al, and TiO₂.

32. The component of claim 25, wherein the main part including the metal surface is formed of stainless steel.

33. The component of claim 32, wherein the stainless steel has a material number 1.4016.
